(19) United States
(12) Patent Application Publication
(10) Pub. No.: US 2010/0116198 A1
(43) Pub. Date: May 13, 2010

(54) METHOD OF PROTECTING CARBONACEOUS CRUCIBLE AND SINGLE-CRYSTAL PULLING APPARATUS

(75) Inventors: Yoshiaki Hirose, Mitoyo-shi (JP); Tetsuya Yuki, Mitoyo-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: TOYO TANSO CO., LTD., Osaka-shi, Osaka (JP)

(21) Appl. No.: 12/594,690

(22) PCT Filed: Apr. 4, 2008
(86) PCT No.: PCT/JP2008/056753

§ 371 Date: Oct. 5, 2009

(30) Foreign Application Priority Data
Apr. 6, 2007 (JP) 2007-100472

(51) Int. Cl. C30B 15/10; B32B 37/18

(52) U.S. Cl. 117/208; 156/293

(57) ABSTRACT

A method is provided of protecting a carbonaceous crucible that is easy to handle, reduces work hour, and can cover the inner surface of a crucible without breaking the sheet and without gaps. A single-crystal pulling apparatus is also provided. The method of protecting a carbonaceous crucible by interposing a protective sheet made of an expanded graphite material between a quartz crucible and a carbonaceous crucible on which the quartz crucible is placed, including: laying two or more protective sheet pieces on an inner surface of the carbonaceous crucible, each of the protective sheet pieces having such a shape that the protective sheet pieces are combined integrally to form the protective sheet in laying the protective sheet between the crucibles.

### TECHNICAL FIELD

The present invention relates to a method of protecting a carbonaceous crucible, and a single-crystal pulling apparatus. More particularly, the invention relates to a method of protecting a carbonaceous crucible of a crucible apparatus having a quartz crucible and a carbonaceous crucible in which the quartz crucible is inserted, especially a single crystal pulling melting crucible apparatus, and a single-crystal pulling apparatus employing the protecting method.

### BACKGROUND ART

Conventionally, a crucible apparatus having a graphite crucible and a quartz crucible has been used typically as a single crystal pulling melting crucible apparatus. A typical single-crystal pulling apparatus in a semiconductor manufacturing process is a single-crystal pulling apparatus for a Czochralski process (the process is hereinafter referred to as a “CZ process,” and the apparatus is referred to as a “CZ apparatus”). In this single-crystal pulling apparatus for the CZ process, a graphite crucible and a quartz crucible are directly in contact with each other. Therefore, the contact surface of the graphite crucible that is in contact with the quartz crucible turns into silicon carbide (hereinafter SiC) because of the reaction between the quartz crucible and the carbonaceous crucible, or the reaction with the SiO gas or the like that originates from Si, resulting in defects such as cracks, due to the difference in thermal expansion coefficient between SiC and graphite. In order to solve such a problem, it has been proposed that a protective sheet made of an expanded graphite material (hereinafter also referred simply to as an “expanded graphite sheet”) is interposed between the quartz crucible and the graphite crucible so as to cover the inner surface of the graphite crucible, whereby breakage of the graphite crucible can be prevented to keep the life of the apparatus long (for example, see Patent Document 1).

[Patent Document 1] Japanese Patent No. 2528285

### DISCLOSURE OF THE INVENTION

### Problems to be Solved by the Invention

However, the expanded graphite sheet used as the foregoing conventional protective sheet is a one-piece sheet, so the following problem occurs when installing the sheet on the inner surface of the crucible.

(1) Since the inner surface of the graphite crucible has a curved surface shape, it is difficult to cover the graphite crucible inner surface with one piece of expanded graphite sheet without gaps.

(2) The expanded graphite sheet has the feature that it is weak in strength since it is made by compressing flocculent expanded graphite. For this reason, an expanded graphite sheet that is a one-piece sheet may be broken or bent when it is attempted to fit along the inner surface of the crucible. On the other hand, a long work hour is necessary when it is attempted to fit such a one-piece expanded graphite sheet along the inner surface of the graphite crucible without breaking the sheet.

(3) Moreover, the size of each one graphite sheet tends to become larger as the size of the crucible has become greater. As a consequence, the problems of the breakage of the expanded graphite sheet and the poor workability resulting in long work hours have become more serious.

Patent Document 1 discloses a one-piece expanded graphite sheet in which a cut is formed in the lower face (see FIGS. 6 and 7 of Patent Document 1), but this is a one-piece protective sheet all the same, which has the same problems as described in the foregoing (1) to (3).

The present invention has been accomplished in view of the foregoing circumstances. It is an object of the invention to provide a method for protecting a carbonaceous crucible that remarkably lessens the work hours, is capable of covering the inner surface without breaking the sheet or without gaps, and is suitable for size increase of the crucible, and to provide a single-crystal pulling apparatus employing the method.

### Means for Solving the Problems

In order to accomplish the foregoing object, the present invention provides a method of protecting a carbonaceous crucible, comprising: interposing a protective sheet made of an expanded graphite material between a quartz crucible and a carbonaceous crucible on which the quartz crucible is placed; and installing two or more protective sheet pieces on an inner surface of the carbonaceous crucible, each of the protective sheet pieces having a shape such that the sheet pieces are combined integrally to form the protective sheet in installing the protective sheet between the crucibles.

Here, the term “carbonaceous crucible” is intended to mean a crucible including both a graphite crucible made of a graphite material and a crucible made of a carbon fiber-reinforced carbon composite material (what is called a C/C material, the crucible hereinafter referred to as a “C/C crucible”). Of course, the graphite crucible and the C/C crucible may be subjected to coating or impregnation with pyrocarbon or the like.

When installing two or more protective sheet pieces on the inner surface of the carbonaceous crucible, each having a shape such that they are combined integrally in installing the protective sheet pieces between the crucibles to form the protective sheet, the workability improves remarkably and the required work hour reduces significantly in comparison with when installing the one-piece protective sheet itself on the inner surface of the carbonaceous crucible. In particular, when a one-piece protective sheet is used for a large-sized crucible, the size becomes considerably large, and handling becomes difficult. Moreover, the installing work requires a long time because the sheet is installed so as to fit along the inner surface of the carbonaceous crucible without breaking the sheet. In contrast, when using a plurality of separate protective sheet pieces, handling is easy, and the work hour reduces. In addition, when the sheet is cut and split into dimensions and shapes such that the sheet pieces can be easily installed along the crucible inner surface in a curved surface shape, good shape-conforming capability is obtained, so the crucible inner surface can be covered without gaps. Furthermore, by splitting the sheet into a plurality of sheet pieces, the sheet can be transported separately in a desirable number. As a result, the transportation of the sheet is easier than when a one-piece sheet is transported.

In the present invention, it is preferable that each of the protective sheet pieces have securing means for securing the adjacent protective sheet pieces to each other in a condition in which the protective sheet pieces are installed on the inner surface of the carbonaceous crucible.

The expanded graphite sheet shows high self-lubricating capability. Therefore, the protective sheet pieces may slip when they are installed on the inner surface of the carbonaceous crucible, causing misalignment. When each of the protective sheet pieces has securing means for securing adjacent protective sheet pieces to each other, misalignment does not easily occur. As a result, they can reliably cover the location in the crucible inner surface that tends to turn into SiC.

In the present invention, the protective sheet pieces that are adjacent to each other are installed in such a manner that substantially no gap or no overlap forms in the inner surface of the carbonaceous crucible.

When the protective sheet pieces that are adjacent to each other are installed in such a manner that substantially no gap forms, it is possible to completely cover the location in the carbonaceous crucible inner surface that is likely to turn into SiC easily. This improves the prevention of turning into SiC of the carbonaceous crucible inner surface. Moreover, since the protective sheet pieces that are adjacent to each other are installed in such a manner that there is little overlap therebetween, it is possible to make the temperature distribution over the entire carbonaceous crucible uniform, preventing the carbonaceous crucible from cracks. The reason is that, when the protective sheet pieces that are adjacent to each other are installed with overlaps, temperature uneveness occurs in the overlapped portion, so a uniform temperature distribution does not form over the entire carbonaceous crucible. This may result in cracks when the carbonaceous crucible undergoes thermal expansion.

In the present invention, there may be a case wherein: the carbonaceous crucible is made of a graphite material; the carbonaceous crucible is formed of a plurality of separate crucible portions that are butt jointed together; and the protective sheet pieces are installed on the inner surface of the carbonaceous crucible in such a manner that the protective sheet pieces cover at least the butt joint portion.

When the carbonaceous crucible is a graphite crucible, the crucible is formed of a plurality of separate crucible portions that are butt jointed to each other. It is known that SiO gas passes through a butt joint portion (what is called a divided surface), so the butt joint portions selectively turn into SiC. In view of this, the sheet is split into a plurality of strips, and the split protective sheet pieces are installed along the butt joint portions. As a result, it becomes possible to prevent the graphite crucible from breaking and prolong the life.

In the present invention, it is preferable that the protective sheet pieces be installed so as to cover at least a portion of the inner surface of the carbonaceous crucible that easily turns into SiC, that is, a curved surface portion from the bottom portion of the crucible toward the straight trunk portion thereof, or the entirety of the carbonaceous crucible, when the carbonaceous crucible is a crucible made of a carbon fiber-reinforced carbon composite material (hereinafter referred to as a “C/C crucible”).

In the case of the C/C crucible, SiO gas passes through the entirety of the crucible inner surface. Therefore, the protective sheet pieces are installed so as to cover the entirety of the inner surface of the carbonaceous crucible. Thereby, it is possible to prevent the C/C crucible from breaking and to prolong the life.

In addition, the present invention provides a single-crystal pulling apparatus using the above-described method of protecting a carbonaceous crucible. By applying this method to a pulling apparatus of a silicon single crystal or the like, it becomes possible to perform uniform heating and to manufacture a silicon single crystal that shows few crystal defects.

### ADVANTAGES OF THE INVENTION

According to the present invention, when installing two or more protective sheet pieces on the inner surface of the carbonaceous crucible, each having a shape such that they are combined integrally in installing the protective sheet pieces between the crucibles to form the protective sheet, the workability improves remarkably and the required work hour reduces significantly in comparison with when installing the single sheet protective sheet itself on the inner surface of the carbonaceous crucible. In particular, when a single sheet protective sheet is used for a large-sized crucible, the size becomes considerably large, and handling becomes difficult. Moreover, the installing work requires a long time because the sheet is installed so as to fit along the inner surface of the carbonaceous crucible without breaking the sheet. In contrast, when using a plurality of separate protective sheet pieces, handling is easy, and the work hour reduces. In addition, when the sheet is cut and split into dimensions and shapes such that the sheet pieces can be easily installed along the crucible inner surface in a curved surface shape, good shape-conforming capability is obtained, so the crucible inner surface can be covered without gaps. Furthermore, by splitting the sheet into a plurality of sheet pieces, the sheet can be transported separately in a desirable number. As a result, the transportation of the sheet is easier than when a single piece sheet is transported.

### BEST MODE FOR CARRYING OUT THE INVENTION

Hereinbelow, the present invention will be described based on the preferred embodiments. It should be noted that the present invention is not limited to the following embodiments.

First, a schematic configuration of crucibles in the single-crystal pulling apparatus shown in FIG. 1 of the present invention will be described, and then, a method of protecting the inner surface of the carbonaceous crucible using the protective sheet according to the present invention will be described.

### (Configuration of Single-Crystal Pulling Apparatus)

FIG. 1 is a cross-sectional view illustrating a primary portion of the single-crystal pulling apparatus. FIG. 2 is an enlarged cross-sectional view of the crucible.

As illustrated in FIG. 1, the CZ apparatus comprises a carbonaceous crucible 2 that supports a quartz crucible 1, a heater 3, an upper ring 4, an inner shield 5, and so forth. Thus, the CZ apparatus obtains a single crystal 7 by heating a source material in the quartz crucible 1 to a high temperature by the heater 3 disposed around the quartz crucible 1 to obtain a source material melt 6, and pulling the source material melt 6.

As illustrated in FIG. 1, the carbonaceous crucible 2 is directly in contact with the quartz crucible 1. For this reason, the surface of the carbonaceous crucible 2 that is in contact with the quartz crucible 1 turns into silicon carbide (hereinafter SiC), because of the reaction between the quartz crucible and the carbonaceous crucible, or the reaction with the SiO gas or the like that originates from Si, resulting in defects such as cracks, due to the difference in thermal expansion coefficient between SiC and graphite. In order to solve the just-mentioned problem, a protective sheet 10 made of an expanded graphite material according to the present invention is interposed between the quartz crucible 1 and the carbonaceous crucible 2, as illustrated in FIG. 2. The protective sheet 10 according to the present invention comprises a plurality of split protective sheet pieces. In other words, a protective sheet made of one sheet of expanded graphite material is split into a plurality of pieces, and the split protective sheet pieces are installed on the inner surface of the carbonaceous crucible 2 without gaps.

### (How Protective Sheet Pieces are Laid)

The types of the carbonaceous crucible 2 include a graphite crucible made of a graphite material, and a crucible formed of a carbon fiber-reinforced carbon composite material (C/C material: hereinafter, this crucible is referred to as a “C/C crucible”). In the case of the graphite crucible, separate crucible portions divided into, for example, two pieces or three pieces are butt jointed to form a crucible, considering the convenience in transportation. It is known that, from the butt joint portions (what is called divided surfaces), SiO gas passes through, so the butt joint portions selectively turn into SiC. In view of this, one piece of protective sheet formed into a strip is split into a plurality of strips, and the split protective sheet pieces 10A are installed along a butt joint portion 11, as illustrated in FIG. 3. FIG. 3 shows an example in which the sheet is split into two pieces, but it is possible to split the sheet into three or four pieces, for example. It is also possible to split the sheet into equal parts, but may be split into various sizes.

In the case of the C/C material crucible, it is preferable that the sheet be installed along the entire inner surface of the crucible. Accordingly, as illustrated in FIG. 4, one piece of protective sheet is split in such a manner that the upper portion is split into strips and the lower portion is split to have a curved surface shape that fits along a bottom portion of the spherical shape, and the split protective sheet pieces 10B are installed along the entire inner surface of the C/C material crucible. It should be noted that the way of splitting is not limited to this, but the sheep may be split into a spherical bottom portion of the spherical shape and an inner circumferential portion, and the inner circumferential portion is further split into a plurality of stripes.

When the protective sheet made of one piece of expanded graphite material is cut and split into predetermined shapes and dimensions and the split protective sheet pieces are installed on the inner surface of the carbonaceous crucible, the protective sheet pieces easily fit along the crucible inner surface in a curved surface shape. As a result, it is possible to cover the butt joint portion, which tends to turn into SiC easily, without gas in the case of the graphite crucible, and to cover the entire crucible inner surface in the case of the C/C material crucible. As a result, prevention of turning into SiC of the inner surface of the carbonaceous crucible 5 is improved.

Moreover, by using split protective sheet pieces, handling becomes easy and workability improves in comparison with when using one-piece protective sheet. Therefore, even when the size of the crucible increases, the protective sheet can be installed on the crucible inner surface without breaking the sheet or taking many work hours.

In addition, the expanded graphite sheet shows high self-lubricating capability. Therefore, the protective sheet pieces may slip when they are laid on the inner surface of the carbonaceous crucible, causing misalignment. In particular, when inserting the quartz crucible after the protective sheet pieces are installed on the carbonaceous crucible inner surface, the quartz crucible makes contact with the installed protective sheet pieces, and misalignment may occur, because the gap between the carbonaceous crucible and the quartz crucible is extremely small. In view of this, each of the protective sheet pieces may have a securing means such as to secure the protective sheet pieces that are adjacent to each other, so that misalignment does not occur in the protective sheet pieces that have been once installed at predetermined positions. An example of the securing means is a configuration in which a protruding portion is provided on an end part of one of the protective sheet pieces that are adjacent to each other while a recessed portion in which the protruding portion fits is provided in an end part of another protective sheet piece, so that the protective sheet can be installed by inserting the protruding portion into the recessed portion. Another example of the method may be a configuration in which a cut is formed in an end of one of the protective sheet pieces, and another protective sheet piece is inserted into the cut. Of course, other securing method may be used. In short, any method may be used as long as the protective sheet pieces that are adjacent to each other can be secured.

### (Manufacturing Method of Protective Sheet Piece)

The protective sheet pieces may be manufactured in the following manner. A one-piece expanded graphite sheet is a sheet-like material made from expanded graphite, and a typical example is as follows. First, natural or synthetic graphite flakes, kish graphite, or the like are treated with an oxidizing agent, to form an intercalation compound in the graphite particles. Next, this is heated to a high temperature, or preferably exposed abruptly to a high temperature to expand rapidly. This treatment causes graphite particles to expand in a direction perpendicular to the layer plane due to the gas pressure of an intercalation compound of the graphite particles, and the volume expands from about 100 times to 250 times. The oxidizing agent used in this case is one that forms an intercalation compound, such as a mixed acid of a sulfuric acid and a nitric acid, and a sulfuric acid to which an oxidizing agent such that a sodium nitride, a potassium permanganate, or the like is added.

Next, impurities are removed to an ash content of 50 ppm or less, preferably 30 ppm or less, and the expanded graphite is formed into a sheet shape by compressing or roll-forming, to prepare an expanded graphite sheet.

Next, the expanded graphite sheet manufactured in the just-described method are cut and split into predetermined dimensions and shapes, to prepare the protective sheet pieces.

### Examples

Hereinbelow, the present invention will be described in detail by examples. It should be noted that the present invention is in no way limited to the following examples.

### Example 1

Protective sheet pieces split into two pieces and prepared in the same manner as described in the foregoing embodiment (hereinafter referred to as a present invention sheet pieces A1) were installed along the butt joint portion of a graphite crucible that was identical to that described in the foregoing embodiment (a graphite crucible divided into two pieces) and that had a size of 22 inches, and an actual machine test for the CZ apparatus was conducted 50 times. The time required for installing the protective sheet pieces on the graphite crucible (work hour), the proportion of the protective sheet pieces that broke and became unable to use (defective rate), and the durability of the graphite crucible were determined by the test. The results are shown in Table 1.

TABLE 1

| | Work hour | Defective | |
|---|---|---|---|
| Type of sheet (sheet piece) | (min.) | rate (%) | Durability |
| Present invention sheet | 5 | 0 | — |
| piece A1 | | | |
| Present invention sheet | 10 | 0 | — |
| piece A2 | | | |
| Comparative sheet Z1 | 7 | 10 | Equivalent to A1 |
| Comparative sheet Z2 | 20 | 20 | Equivalent to A2 |

### Example 2

An actual machine test was conducted under the same conditions as those in Example 1, except that the size of the graphite crucible was 40 inches and that protective sheet pieces, which are split into two pieces, having a corresponding size (hereinafter referred to as a present invention sheet piece A2) were used, to determine the work hour, the defective rate, and the durability. The results are shown in Table 1.

### Comparative Example 1

An actual machine test was conducted under the same conditions as those in Example 1, except that one-piece strip-shaped protective sheet that is not split into two pieces (hereinafter referred to as a comparative sheet Z1) was used, to determine the work hour, the defective rate, and the durability. The results are shown in Table 1.

### Comparative Example 2

An actual machine test was conducted under the same conditions as those in Example 1, except that the size of the graphite crucible was 40 inches and that one-piece strip-shaped protective sheet (hereinafter referred to as a comparative sheet Z2) having a corresponding size to the crucible size was used, to determine the work hour, the defective rate, and the durability. The results are shown in Table 1.

### Example 3

Protective sheet pieces that were split in the same manner as described in the foregoing embodiment (hereinafter referred to as a present invention sheet pieces B1) were installed on the inner surface of a C/C crucible that was identical to that described in the foregoing embodiment and that had a size of 22 inches, so as to cover the entire inner surface of the C/C crucible, and an actual machine test for the CZ apparatus was conducted 50 times. The time required for installing the protective sheet pieces on the C/C crucible (work hour), the proportion of the protective sheet pieces that broke and became unable to use (defective rate), and the durability of the graphite crucible were determined by the test. The results are shown in Table 2.

TABLE 2

| | Work hour | Defective | |
|---|---|---|---|
| Type of sheet (sheet piece) | (min.) | rate (%) | Durability |
| Present invention sheet | 10 | 0 | — |
| piece B1 | | | |
| Present invention sheet | 20 | 0 | — |
| piece B2 | | | |
| Comparative sheet Y1 | 20 | 30 | Shorter than B1 |
| Comparative sheet Y2 | 40 | 50 | Shorter than B2 |

### Example 4

An actual machine test was conducted under the same conditions as those in Example 3, except that the size of the C/C crucible was 40 inches and that protective sheet pieces having a corresponding size and split (hereinafter referred to as a present invention sheet piece B2) were used, to determine the work hour, the defective rate, and the durability. The results are shown in Table 2.

### Comparative Example 3

An actual machine test was conducted under the same conditions as those in Example 3, except that one-piece protective sheet that is not split into two pieces (hereinafter referred to as a comparative sheet Y1) was used, to determine the work hour, the defective rate, and the durability. The results are shown in Table 2.

### Comparative Example 4

An actual machine test was conducted under the same conditions as those in Example 3, except that the size of the C/C crucible was 40 inches and that a one-piece protective sheet having a corresponding size (hereinafter referred to as a comparative sheet Y2) was used, to determine the work hour, the defective rate, and the durability. The results are shown in Table 2.

### (Analysis of the Test Results)

As clearly seen from Tables 1 and 2, the present invention sheet pieces A1, A2, B1, and B2 are better in durability than the comparative sheets Z1, Z2, Y1, and Y2, when judging the results comprehensively. It is also understood that the present invention sheet pieces A1, A2, B1, and B2 are far better in work hour and defective rate than the comparative sheets Z1, Z2, Y1, and Y2.

In particular, when comparing the defective rates between the 22-inch crucible and the 40-inch crucible, considerably higher defective rates are observed with the crucibles having a greater size, in the case of the comparative sheets Z1, Z2, Y1, and Y2. In contrast, it is demonstrated that, in the cases of the present invention sheet pieces A1, A2, B1, and B2, the defective rate stays at 0% even when the crucible size increases. Therefore, it is believed that the protecting method using the present invention sheet piece is suitable for large-sized crucibles.

### INDUSTRIAL APPLICABILITY

The present invention is suitable for a method of protecting a carbonaceous crucible in a single crystal pulling crucible apparatus according to a CZ method.

### BRIEF DESCRIPTION OF THE DRAWINGS

FIG. 1 is a cross-sectional view illustrating a primary portion of a single-crystal pulling apparatus.

FIG. 2 is an enlarged cross-sectional view of a crucible.

FIG. 3 is a view illustrating an embodiment of how protective sheet pieces are installed.

FIG. 4 is a view illustrating another embodiment of how protective sheet pieces are installed.

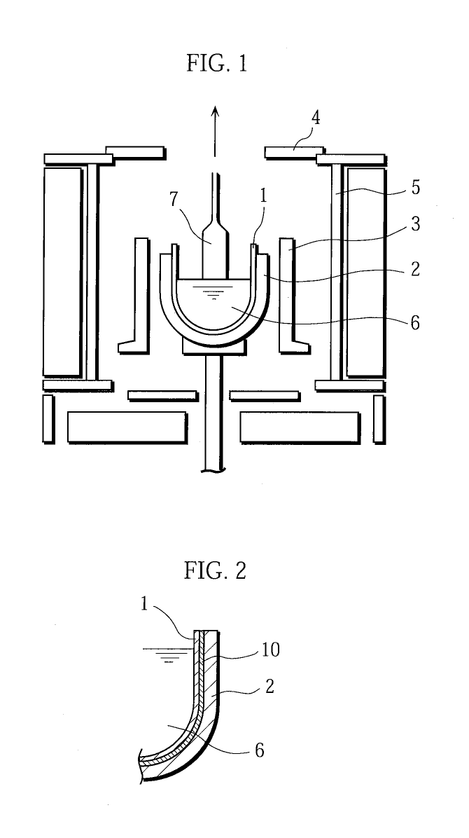

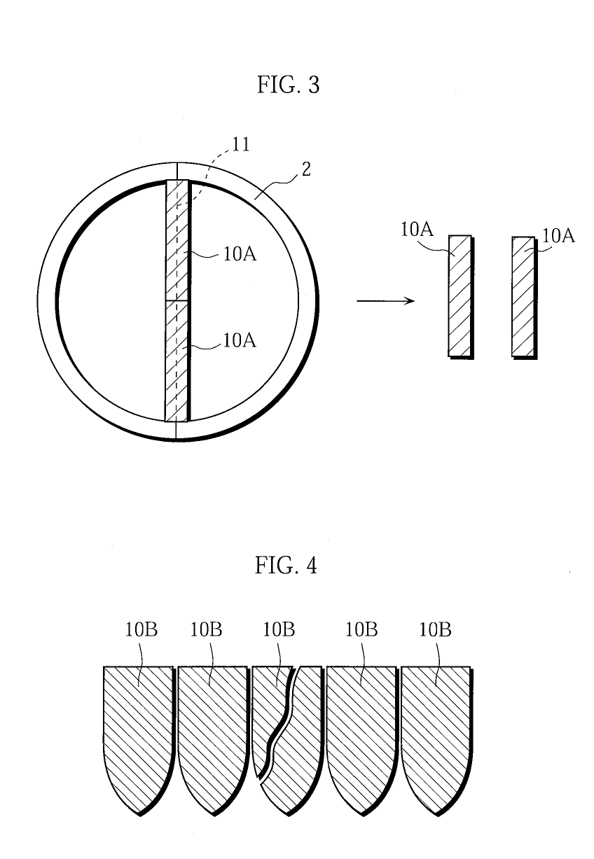

### DESCRIPTION OF REFERENCE NUMERALS

1: quartz crucible

2: carbonaceous crucible

3: heater

4: upper ring

5: inner shield

6: source material melt

7: single crystal

10A, 10B: protective sheet pieces

11: butt joint portion

1. A method of protecting a carbonaceous crucible by interposing a protective sheet made of an expanded graphite material between a quartz crucible and a carbonaceous crucible on which the quartz crucible is placed, comprising:
installing two or more protective sheet pieces on an inner surface of the carbonaceous crucible, each of the protective sheet pieces having such a shape that the protective sheet pieces are combined integrally to form the protective sheet in installing the protective sheet between the crucibles.

2. The method of protecting a carbonaceous crucible according to claim 1, wherein each of the protective sheet pieces comprises securing means for securing the protective sheet pieces that are adjacent to each other in a condition in which the protective sheet pieces are installed on the inner surface of the carbonaceous crucible.

3. The method of protecting a carbonaceous crucible according to claim 1, wherein the protective sheet pieces that are adjacent to each other are installed in such a manner that substantially no gap or no overlap therebetween in the inner surface of the carbonaceous crucible.

4. The method of protecting a carbonaceous crucible according to claim 1, wherein: the carbonaceous crucible is made of a graphite material; the carbonaceous crucible is formed of a plurality of separate crucible portions that are butt jointed together; and the protective sheet pieces are installed on the inner surface of the carbonaceous crucible in such a manner that the protective sheet pieces cover at least the butt joint portion.

5. The method of protecting a carbonaceous crucible according to claim 1, wherein the carbonaceous crucible is a carbon fiber-reinforced carbon composite material, and the protective sheet pieces are installed so as to cover the entire inner surface of the carbonaceous crucible.

6. A single-crystal pulling apparatus using a method of protecting a carbonaceous crucible according to claim 1.
